(19) United States
(12) Patent Application Publication
(10) Pub. No.: US 2015/0380903 A1
(43) Pub. Date: Dec. 31, 2015

(54) SURFACE EMITTING LASER AND OPTICAL COHERENCE TOMOGRAPHY USING THE SURFACE EMITTING LASER

(71) Applicant: CANON KABUSHIKI KAISHA, Tokyo (JP)

(72) Inventor: Yasuhiro Nagatomo, Kawasaki-shi (JP)

(21) Appl. No.: 14/754,935

(22) Filed: Jun. 30, 2015

(30) Foreign Application Priority Data
Jun. 30, 2014 (JP) 2014-135389

(51) Int. Cl. H01S 5/183; G01B 9/02

(52) U.S. Cl. CPC H01S 5/18361; G01B 9/02091

(57) ABSTRACT

A surface emitting laser including a lower reflecting mirror, an active layer, and an upper reflecting mirror in that order, having an air gap between the active layer and the upper reflecting mirror, and being able to change a wavelength of light to be emitted, includes a light-intensity adjustment unit provided on an optical path of the air gap and having optical absorption or optical gain in a wavelength range of emission light of the surface emitting laser. The wavelength of the light to be emitted is changed by displacing the light-intensity adjustment unit and at least one of the upper reflecting mirror and the lower reflecting mirror.

### BACKGROUND OF THE INVENTION

1. Field of the Invention

The present invention relates to a wavelength variable surface emitting laser, and an optical coherence tomography using the surface emitting laser.

2. Description of the Related Art

Since a wavelength variable laser that can change its laser oscillation wavelength is expected to be applied to various fields such as communication, sensing, and imaging, the wavelength variable laser is actively studied and developed in recent years.

There is known, as a type of wavelength variable laser, a wavelength variable VCSEL structure that controls the laser oscillation wavelength of a vertical cavity surface emitting laser by micro electro mechanical systems (MEMS) technology. Hereinafter, a vertical cavity surface emitting laser may be occasionally referred to as VCSEL, and a wavelength variable VCSEL using MEMS may be occasionally referred to as MEMS-VCSEL.

VCSEL is typically configured such that an active layer is sandwiched between a pair of reflecting mirrors such as distributed Bragg reflectors (DBRs), and oscillates a laser beam with a wavelength corresponding to a cavity length that is determined by an optical distance between the pair of reflecting mirrors. In MEMS-VCSEL, the laser oscillation wavelength can be changed by mechanically moving the position of one of the reflecting mirrors and hence changing the cavity length (the specification of U.S. Pat. No. 6,549,687).

### SUMMARY OF THE INVENTION

In VCSEL of related art described in the specification of U.S. Pat. No. 6,549,687, the inventor of the present invention found that a mode hop phenomenon occurs if the wavelength is continuously changed. A mode hop is a phenomenon in which an oscillated laser beam is changed from a certain longitudinal mode to another longitudinal mode. To be specific, in the phenomenon, the oscillation wavelength becomes rapidly short while the oscillation wavelength is changed to become long, or the oscillation wavelength becomes rapidly long while the oscillation wavelength is changed to become short. If such a mode hop occurs, when the oscillation wavelength is changed, the oscillation is hardly continued in a certain mode. Hence, the variable width of the oscillation wavelength becomes small.

Accordingly, the invention provides a surface emitting laser that can enlarge a wavelength variable width by restricting a mode hop of a longitudinal mode.

According to an aspect of the invention, there is provided a surface emitting laser including a lower reflecting mirror, an active layer, and an upper reflecting mirror in that order, having an air gap between the active layer and the upper reflecting mirror, and being able to change a wavelength of light to be emitted. The surface emitting laser includes a light-intensity adjustment unit provided on an optical path of the air gap and having optical absorption or optical gain in a wavelength range of emission light of the surface emitting laser. The wavelength of the light to be emitted is changed by displacing the light-intensity adjustment unit and at least one of the upper reflecting mirror and the lower reflecting mirror.

Further features of the present invention will become apparent from the following description of exemplary embodiments with reference to the attached drawings.

### BRIEF DESCRIPTION OF THE DRAWINGS

FIG. 1 is a schematic cross-sectional view showing a structure of a surface emitting laser according to an exemplary embodiment of the invention.

FIGS. 2A to 2C are illustrations explaining drive patterns of the surface emitting laser according to the exemplary embodiment of the invention.

FIGS. 3A to 3C illustrate calculation results indicative of light-intensity distributions of the surface emitting laser according to the exemplary embodiment of the invention.

FIGS. 4A and 4B illustrate calculation results indicative of optical characteristics of the surface emitting laser according to the exemplary embodiment of the invention.

FIG. 5 illustrates a calculation result indicative of thickness dependency of a light-intensity adjustment unit according to the exemplary embodiment of the invention.

FIG. 6 is a schematic illustration showing an optical coherence tomography according to the exemplary embodiment of the invention.

FIG. 7 is a schematic cross-sectional view showing a structure of VCSEL according to EXAMPLE 1 of the invention.

FIGS. 8A and 8B are schematic cross-sectional views showing optical characteristics of VCSEL according to EXAMPLE 1 of the invention.

FIG. 9 is a schematic cross-sectional view showing a structure of MEMS-VCSEL of related art.

FIGS. 10A and 10B illustrate calculation results explaining a problem of MEMS-VCSEL of related art.

FIG. 11 is a schematic cross-sectional view explaining an example configuration of a surface emitting laser according to EXAMPLE 2 of the invention.

FIG. 12 is a schematic cross-sectional view explaining an example configuration of a surface emitting laser according to EXAMPLE 3 of the invention.

### DESCRIPTION OF THE EMBODIMENTS

A wavelength variable vertical cavity surface emitting laser (VCSEL) according to an exemplary embodiment of the invention is described below.

First, words to be used in this specification are defined.

In this specification, the side near a substrate of a laser element is defined as the lower side, and the side opposite to the substrate is defined as the upper side.

In this specification, a center wavelength is used as a wavelength at the center of a wavelength range of a laser beam that can be emitted from a surface emitting laser. That is, the center wavelength represents the wavelength at the center between the shortest wavelength and the longest wavelength that can be provided by laser oscillation. The wavelength that can be provided by laser oscillation is determined by the variation width of a cavity length, the reflection band of a reflecting mirror, the gain band of an active layer, etc. At the time of design, the center wavelength is basically set and configurations of respective elements are determined in accordance with the center wavelength. Also, in this specification, the “center” of a light-intensity adjustment unit or an active layer represents the position at a half of the thickness in an optical-axis direction. The optical-axis direction is a direction connecting an upper reflecting mirror and a lower reflecting mirror (described later) and a direction perpendicular to a principal surface of a substrate.

Also, in this specification, 1λ represents 1 wavelength. The wavelength at this time is the center wavelength unless otherwise noted.

The calculation result in this specification was obtained by calculating a distribution of electromagnetic fields in a cavity by using a transfer matrix method with regard to boundary conditions of Maxwell's equations.

### Surface Emitting Laser

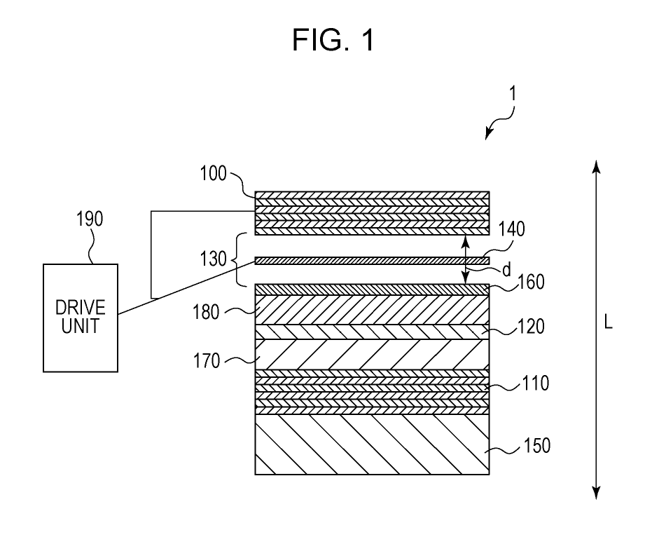

FIG. 1 is a schematic cross-sectional view showing a configuration of a surface emitting laser that can change the wavelength of a laser beam to be emitted according to this exemplary embodiment.

A surface emitting laser 1 according to this exemplary embodiment includes a substrate 150, a lower reflecting mirror 110, a lower cladding layer 170, an active layer 120, an upper cladding layer 180, an antireflection film 160, an air gap 130, and an upper reflecting mirror 100 arranged in that order.

A light-intensity adjustment unit 140 is provided on an optical path of the air gap 130. The light-intensity adjustment unit 140 has optical absorption or optical gain within a wavelength range of emission light of the surface emitting laser. In this exemplary embodiment, distributed Bragg reflectors (DBRs) each formed of a multilayer film are used as the upper reflecting mirror 100 and the lower reflecting mirror 110. A region sandwiched between the upper reflecting mirror 100 and the lower reflecting mirror 110 serves as a cavity, and forms a standing light wave. The upper reflecting mirror 100 can be displaced in the optical-axis direction (direction indicated by double sided arrow L in FIG. 1). The air gap 130 has a length d (hereinafter, occasionally referred to as air-gap length) between the upper reflecting mirror 100 and the antireflection film 160. When the length d is changed, the cavity length is changed, and the resonant wavelength is changed. Hence, the surface emitting laser 1 according to this exemplary embodiment uses a drive unit 190 that changes the position of the upper reflecting mirror 100 to change the position of the upper reflecting mirror 100 in the optical-axis direction, and hence changes the air-gap length. Accordingly, the wavelength of light to be emitted can be changed. The length d of the air gap is a distance on the optical axis between a semiconductor stack body including the active layer 120 and the lower reflecting mirror 110, and the upper reflecting mirror 100. In FIG. 1, the length d of the air gap is the distance on the optical axis between the antireflection film 160 and the upper reflecting mirror 100; however, the length d of the air gap may be different depending on the layer configuration of the semiconductor stack body. For example, in FIG. 1, the length d is the distance between the upper reflecting mirror 100 and the upper cladding layer 180 if the antireflection film 160 is not formed, and the length d is the distance between the upper reflecting mirror 100 and the active layer 120 if the antireflection film or the upper cladding layer is not provided.

In the surface emitting laser according to this exemplary embodiment, the positions on the optical path of the light-intensity adjustment unit 140 and at least one of the upper reflecting mirror 100 and the lower reflecting mirror 110 are changed, or the positions on the optical path of the upper reflecting mirror 100 and the lower reflecting mirror 110 are changed. The threshold gain of a specific longitudinal mode is set to be relatively smaller than that of another longitudinal mode, and hence a mode hop can be restricted and the wavelength variable width can be enlarged.

To be specific, the above-described effect can be attained by properly controlling the positional relationship among the upper reflecting mirror, the light-intensity adjustment unit, and the lower reflecting mirror, in accordance with a change in air-gap length and a change in resonant wavelength (laser oscillation wavelength).

The proper control method may be two methods as follows. One method is a method of providing a certain member with optical absorption (optical absorption member) as the light-intensity adjustment unit 140 at a position that is a node of a light distribution in a specific longitudinal mode and that is an antinode of a light distribution in one-order lower and one-order higher longitudinal modes neighbor of the specific longitudinal mode. That is, if the light-intensity adjustment unit 140 is provided at the antinode with a high light intensity in the neighbor longitudinal mode, a decrease in light intensity in the cavity is large. In contrast, if the light-intensity adjustment unit is provided at the node with a low light intensity in the specific mode, a decrease in light intensity in the cavity is small. That is, since the difference in light intensity between the specific longitudinal mode and the neighbor longitudinal mode is increased and the difference in oscillation threshold is increased, oscillation in the specific mode is easily performed and a mode hop is restricted.

Another method is a method of providing a member with optical gain (optical gain medium) as the light-intensity adjustment unit 140 at a position that is an antinode of a light distribution in a specific longitudinal mode and that is a node of a light distribution in one-order lower and one-order higher longitudinal modes neighbor of the specific longitudinal mode. That is, if the light-intensity adjustment unit 140 is provided at the node with a low light intensity in the neighbor longitudinal mode, amplification in light intensity is small. In contrast, if the light-intensity adjustment unit 140 is provided at the antinode with a high light intensity in the specific longitudinal mode, amplification in light intensity is large. That is, since the difference in light intensity between the specific longitudinal mode and the neighbor longitudinal mode is increased and the difference in oscillation threshold is increased, oscillation in the specific mode is easily performed and a mode hop is restricted. However, to allow the light-intensity adjustment unit 140 to have optical gain, since current injection and photoexcitation are performed on the optical gain medium, it is required to provide a structure for current injection and a light source for photoexcitation. In contrast, use of the optical absorption member is more desirable because the structure for current injection or the light source is not required. Therefore, in the following description, an exemplary embodiment of using the optical absorption member as the light-intensity adjustment unit is described unless otherwise noted.

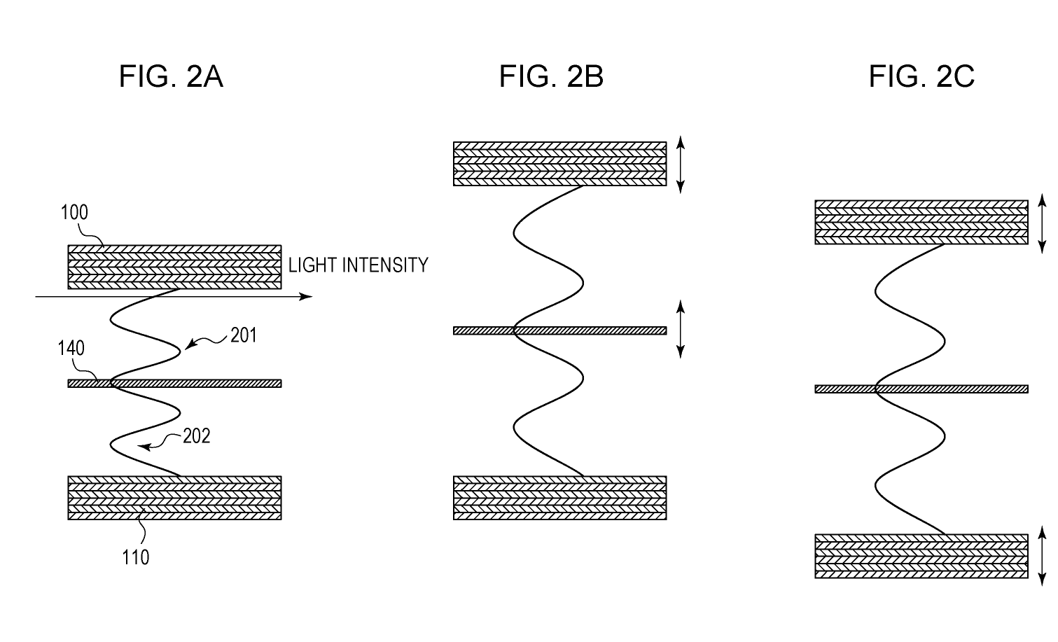

Next, some methods for the above-described provision at the position that is at the antinode of the light distribution in the specific longitudinal mode and that is at the position at the node of the light distribution in the one-order lower and one-order higher longitudinal modes neighbor of the specific longitudinal mode are described with reference to FIGS. 2A to 2C. FIGS. 2A to 2C are schematic illustrations each showing only the upper reflecting mirror 100, the light-intensity adjustment unit (the optical absorption member) 140, and the lower reflecting mirror 110 included in the diagram of the surface emitting laser in FIG. 1. FIGS. 2A to 2C also each show a standing light wave in a specific longitudinal mode formed between the upper reflecting mirror 100 and the lower reflecting mirror 110. The standing light wave (wave line) in each of FIGS. 2A to 2C represents the light intensity. The light intensity is a value proportional to the square of the electric-field intensity amplitude. Reference sign 201 denotes an antinode and 202 denotes a node of a standing light wave. Corresponding positions in FIGS. 2B and 2C are similarly illustrated.

FIG. 2A is an initial state. FIGS. 2B and 2C are illustrations after the reflecting mirrors and the light-intensity adjustment unit are displaced from the initial state in FIG. 2A.

In FIG. 2B, the upper reflecting mirror 100 is displaced on the optical axis, the shape of the standing light wave is changed, and the wavelength becomes long. As the wavelength becomes long, the position of the node of the standing light wave is changed. Hence, the light-intensity adjustment unit 140 is displaced on the optical axis in accordance with the displacement of the upper reflecting mirror 100, so that the light-intensity adjustment unit 140 is constantly provided at the position of the node of the standing light wave. Accordingly, the state in which a mode hop is restricted as described above can be maintained.

Also, as shown in FIG. 2C, a similar effect can be attained without displacement of the light-intensity adjustment unit 140. That is, both the upper reflecting mirror 100 and the lower reflecting mirror 110 are displaced to change the wavelength and the displacement is properly controlled, so that the state in which the light-intensity adjustment unit 140 is constantly provided at the position of the node is maintained.

### Description for Principle

The principle that the effect of the invention is generated is described in detail using calculation examples.

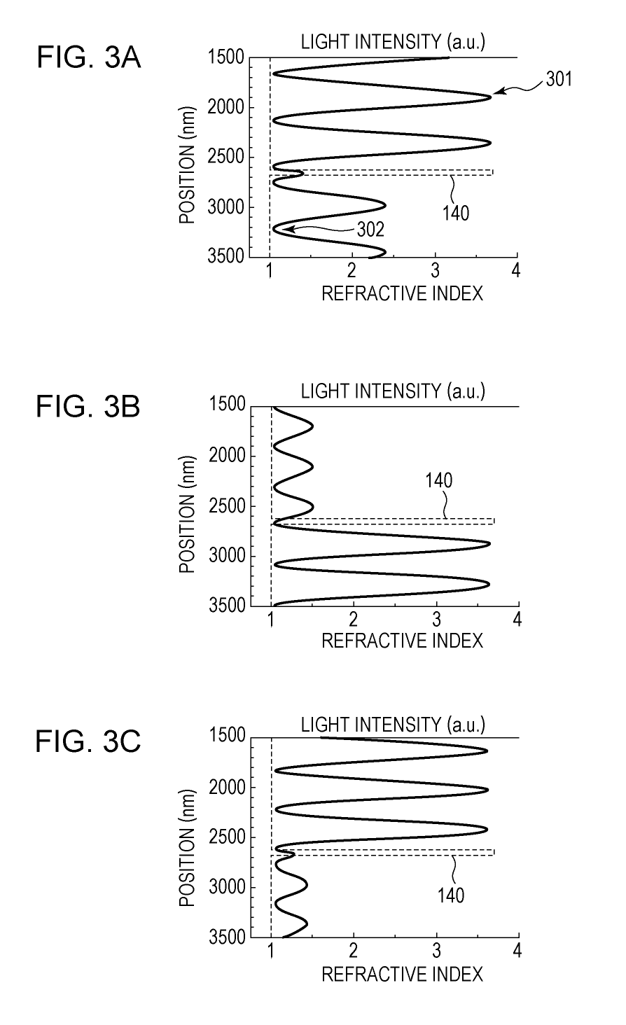

FIGS. 3A to 3C illustrate examples of calculation results for explaining occurrence of differences in light distribution among different longitudinal modes in the surface emitting laser according to this exemplary embodiment. In FIGS. 3A to 3C, the light intensity is a value proportional to the square of the electric-field intensity amplitude. Reference sign 301 is an antinode and 302 denotes a node of a standing light wave. Corresponding positions in FIG. 3B and 3C are similarly illustrated.

The configuration of the surface emitting laser serving as a calculation subject is a case in which the surface emitting laser shown in FIG. 1 has an air-gap length of 3500 nm.

FIGS. 3A to 3C each shows a graph of a light-intensity distribution around the air gap 130. The refractive index distribution is indicated by a broken line, and the light-intensity distribution is indicated by a thick solid line. Numbers in each graph represent respective positions of the light-intensity adjustment unit 140.

FIGS. 3A to 3C show the light-intensity distributions in three different longitudinal modes so that the cavity lengths are 5λ, 5.5λ, and 6λ. In each of FIGS. 3A and 3C, the light-intensity adjustment unit (the optical absorption member) 140 is located near an antinode of the light distribution. In contrast, in FIG. 3B, the light-intensity adjustment unit 140 is located near a node of the light distribution.

If the light-intensity adjustment unit is provided at an antinode of the light distribution, that is, at a position with light gathering as shown in each of FIGS. 3A and 3C, the light is more absorbed. Consequently, a loss occurs in the light moving in the cavity. To compensate the loss, a larger gain is required in the active layer.

In contrast, if the light-intensity adjustment unit is provided at a node of the light distribution, that is, at a position with almost no light as shown in FIG. 3B, the light is less absorbed. Owing to this, the loss of light moving in the cavity is not increased.

As described above, the threshold gains in the one-order lower and one-order higher longitudinal modes shown in FIGS. 3A and 3C are relatively larger than the longitudinal mode shown in FIG. 3B, and the effect of restricting a mode hop is generated.

To increase the difference in threshold gain between the neighbor longitudinal modes, the difference in optical absorption between the longitudinal modes is increased. Owing to this, it is effective to provide the light-intensity adjustment unit 140 near the center of the optical length of the cavity configured of the upper reflecting mirror and the lower reflecting mirror. In this case, there is a difference corresponding to one period of the standing light wave (interval between antinodes) in the entire cavity. At a position near the center of the cavity, a difference corresponding to the interval between the antinode and node being a half of the aforementioned difference is generated. That is, the difference in optical absorption becomes the largest if an antinode in a certain-number-order longitudinal mode with a certain order and a node in a longitudinal mode with the neighbor order appear at the same position and the light-intensity adjustment unit is arranged at that position.

The effect of the invention is the most likely attained if the positions of the antinode and node of the standing light wave are accurately aligned with the center position in the optical-axis direction of the light-intensity adjustment unit. However, the effect of the invention can be attained even if the positions are not accurately aligned with each other. If the light-intensity adjustment unit is arranged near a node of the light distribution, as long as the center position in the optical-axis direction of the light-intensity adjustment unit is located between an antinode and a node and at a position near the node, the threshold gain is decreased as compared with the longitudinal mode with the neighbor order and hence the effect of the invention can be attained. Since the distance between the antinode and node of the standing light wave corresponds to a ¼ wavelength, the distance from the node is only required to be smaller than a half of the distance. That is, the center in the optical-axis direction of the light-intensity adjustment unit is only required to be located within a range of ±⅛ times the center wavelength of the surface emitting laser in the optical-axis direction from a certain node position.

The positions of the antinode and node of the standing light wave are determined on the basis of the laser oscillation wavelength λ the optical distance from the lower reflecting mirror, and the phase change at reflection by the lower reflecting mirror. Hence, the position of the light-intensity adjustment unit can be determined in accordance with these factors.

If the phase change at light reflection by the lower reflecting mirror is 0 and represents free-end reflection, the antinode is located at a distance of λ/2×m and the node is located at a distance of λ/2×(m−1)+λ/4 from the upper end of the lower reflecting mirror (m is a natural number, which will be also applied to the following description).

If the phase change at light reflection by the lower reflecting mirror is π and represents fixed-end reflection, the antinode is located at a distance of λ/2×(m−1)+λ/4 and the node is located at a distance of λ/2×(m−1) from the upper end of the lower reflecting mirror.

If the phase change at light reflection by the lower reflecting mirror is not 0 or π, the antinode and node are located at intermediate positions of the above-described two cases, in accordance with the amount of phase change.

Also, if the upper reflecting mirror is periodically displaced and driven to repetitively perform wavelength sweeping, the light-intensity adjustment unit and the upper reflecting mirror are displaced desirably synchronously, and are displaced desirably in the same period.

### DETAILED DESCRIPTION FOR PROBLEM OF RELATED ART

A problem that is found by the inventor of the present invention is described in detail below. The problem is owned by VCSEL of related art and is that the above-described light-intensity adjustment unit 140 is not provided and a proper light-intensity distribution is not formed.

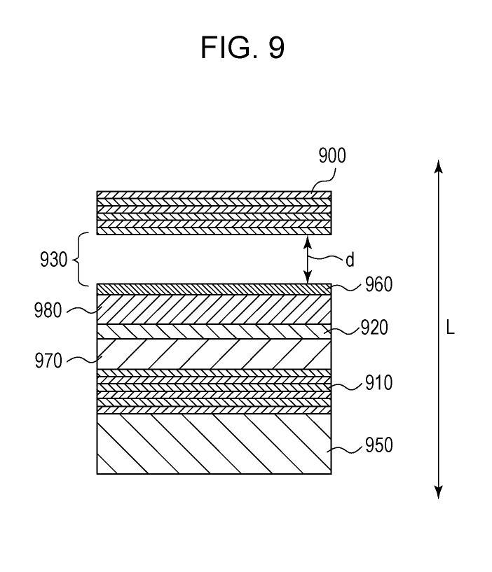

FIG. 9 is a schematic cross-sectional view showing a structure of MEMS-VCSEL of related art.

MEMS-VCSEL in FIG. 9 is configured of a compound semiconductor based on GaAs, has a center wavelength of 850 nm, and is designed so that the wavelength is variable around the center wavelength. A resonant structure in which an active layer 920 and an air gap 930 are sandwiched between an upper reflecting mirror 900 and a lower reflecting mirror 910 is arranged on a substrate 950. Also, the active layer 920 is sandwiched between a lower cladding layer 970 and an upper cladding layer 980.

Also, distributed Bragg reflectors (DBRs) each formed of a multilayer film are used as the upper reflecting mirror and the lower reflecting mirror. An antireflection film 960 is formed between the air gap 930 and the upper cladding layer 980.

The optical distance between the upper reflecting mirror 900 and the lower reflecting mirror 910 is the cavity length. Also, by moving the upper reflecting mirror 900 in the optical-axis direction (L), the length d of the air gap 930 can be changed and hence the cavity length can be changed. Accordingly, the laser oscillation wavelength can be changed.

In general, a plurality of optical modes are present in a cavity. A mode classified on the basis of a difference in light distribution in the optical-axis direction of the cavity is called longitudinal mode, and a mode classified on the basis of a difference in light distribution in a direction perpendicular to the optical axis is called transverse mode.

The order of the longitudinal mode is defined by the number of optical wavelengths involved in the optical distance (cavity length) in the optical-axis direction. A mode involving a smaller number is called low-order longitudinal mode, and a mode involving a larger number is called high-order longitudinal mode.

Here, a state in which laser oscillation occurs in a certain longitudinal mode is considered. When the upper reflecting mirror 900 is moved upward from the state, the cavity length is increased, and the laser oscillation wavelength is shifted to the long wavelength side. The laser oscillation wavelength is continuously changed in accordance with the displacement of the upper reflecting mirror. However, if the displacement of the upper reflecting mirror 900 exceeds a certain value, laser oscillation occurs in a one-order higher longitudinal mode, and the laser oscillation wavelength discontinuously may jump to the short wavelength side.

Similarly, when the upper reflecting mirror 900 is moved downward, the cavity length is decreased, and the laser oscillation wavelength is shifted to the short wavelength side. However, if the displacement of the upper reflecting mirror 900 exceeds a certain value, laser oscillation occurs in a one-order lower longitudinal mode, and the laser oscillation wavelength discontinuously jumps to the long wavelength side.

As described above, a phenomenon, in which the wavelength is discontinuously changed because the mode of laser oscillation is changed, is generally called mode hop.

In MEMS-VCSEL, as the wavelength is continuously changed, a mode hop occurs when the wavelength is changed by a certain degree or more, and the wavelength is changed in the opposite direction. Hence, there is a problem that the wavelength variable width is limited. Described in more detail below is the reason why the wavelength width is narrowed as the result that a mode hop occurs.

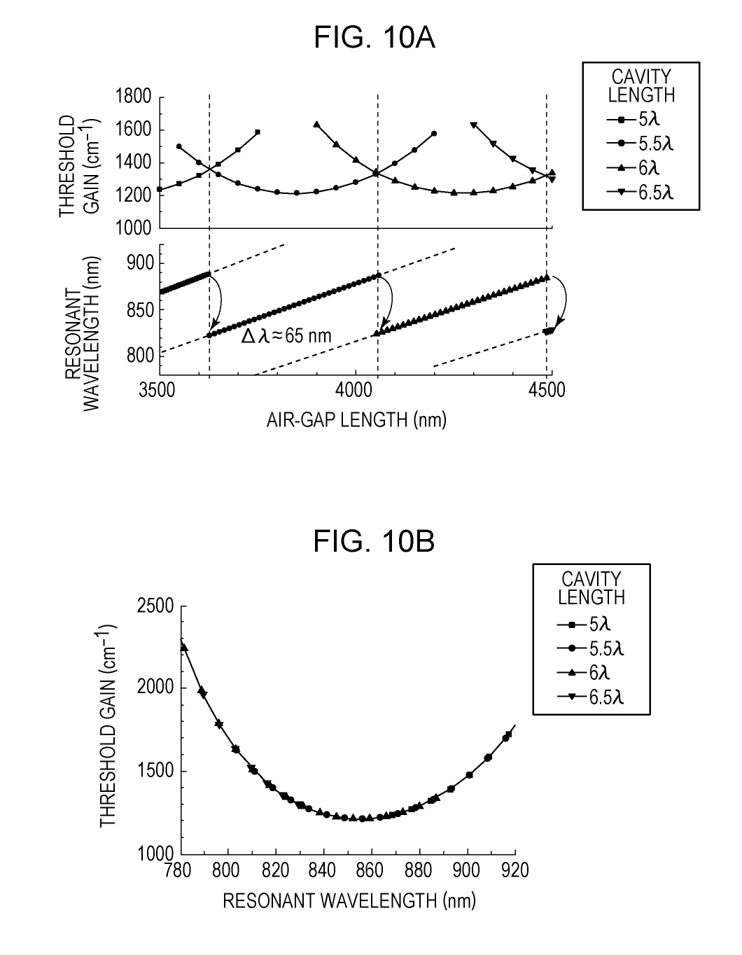

FIG. 10A shows an example of calculation for the relationship of the resonant wavelength and the gain (threshold gain) required for laser oscillation with respect to the length d (air-gap length) of the air gap 930 in the MEMS-VCSEL shown in FIG. 9. If a gain of the threshold gain or larger is provided by the active layer, laser oscillation occurs with the resonant wavelength.

In this calculation, the active layer is configured of a single-layer quantum well layer made of InGaAs with a thickness of 8 nm. Assuming that a gain is generated uniformly in the active layer, the gain per unit length required for laser oscillation was calculated.

In the range of the calculated wavelength and air-gap length, longitudinal modes corresponding to cavity lengths in a range from 5λ to 6.5λ are found. An upper graph in FIG. 10A plots the relationship between the air-gap length and the threshold gain. If the air-gap length is changed, the threshold gain is changed. Hence, it is found that there is a minimum value of the threshold gain for an air-gap length being different for each longitudinal mode.

Focusing on the minimum value of the threshold gain of a certain longitudinal mode, the threshold gain of the longitudinal mode is smaller than the threshold gain of another longitudinal mode while a change in air-gap length from the minimum value is smaller than a certain range. However, if the air-gap length is changed beyond the certain range, the threshold gain of the neighbor order longitudinal mode becomes smaller, and the magnitude relationship of the threshold gains are reversed.

A lower graph in FIG. 10A plots the relationship between the air-gap length and the resonant wavelength. The calculation result for the resonant wavelength in each longitudinal mode is indicated by a broken line. It is found that if the air-gap length is changed, the resonant wavelength in each mode is changed almost proportionally to the change in air-gap length.

A certain wavelength interval is provided between neighbor modes. The interval between the longitudinal modes may be occasionally called free spectral range (FSR).

In general, as the cavity length is increased, the longitudinal mode interval is decreased and the change in resonant wavelength in accordance with the change in air-gap length is also decreased (that is, the gradient of the lower graph in FIG. 10A is decreased). Owing to this, with regard to operation as a wavelength variable laser, the cavity length is desirably 10 wavelengths or smaller.

A resonant wavelength oscillated as a longitudinal mode with the smallest threshold gain read from the upper graph in FIG. 10A is indicated by a line with symbol marks in the lower graph in FIG. 10A.

Referring to FIG. 10A, as the air-gap length is increased, the resonant wavelength is shifted to the long wavelength side. If the amount of change in wavelength becomes a certain amount or larger, the threshold gain of a one-order higher longitudinal mode becomes smaller, and hence a mode hop may occur as indicated by an arrow in the drawing.

If a mode hop occurs, the wavelength is changed in the opposite direction. That is, if the wavelength is changed to be increased, the wavelength becomes discontinuously decreased, and the wavelength is increased again from the wavelength. Hence, the wavelength variable width is limited. For example, the air-gap length with which the wavelength can be continuously changed without occurrence of a mode hop in a longitudinal mode corresponding to a cavity length of 5.5λ is limited in a range from 3600 to 4050 nm. The wavelength variable width in this case is about 65 nm.

FIG. 10B plots again the calculation result in FIG. 10A while the horizontal axis represents the resonant wavelength and the vertical axis represents the threshold gain. Referring to FIG. 10B, the threshold gain is the most decreased around the center wavelength of 850 nm. There may be two reasons. The first reason is that since the DBRs of the upper and lower reflecting mirrors are designed on the basis of the center wavelength 850 nm, the reflectivity is increased as the wavelength approaches to the wavelength of 850 nm. In general, as the reflectivity of a reflecting mirror is higher, laser oscillation can occur with a smaller gain.

The second reason is that since the position of the active layer is designed to be aligned with the antinode of the light distribution with the center wavelength of 850 nm, a positional deviation between the active layer and the antinode of the light distribution is increased as the wavelength is more separated from the wavelength of 850 nm. If the light distribution in the active layer becomes small, the efficiency of optical amplification is decreased, and as the result, the threshold gain is increased.

Referring to FIG. 10B now, it is found that almost all the lines plotted for respective longitudinal modes are substantially overlapped. That is, there is substantially no difference in threshold gain among the longitudinal modes. It is found that the threshold gain is determined mainly on the basis of the wavelength. When laser oscillation occurs with a wavelength around the center wavelength in a certain longitudinal mode, if the air-gap length is changed, the resonant wavelength (laser oscillation wavelength) is separated from the center wavelength, and the threshold gain is increased accordingly. In contrast, the resonant wavelength of one-order higher or one-order lower longitudinal mode approaches to the center wavelength, and the threshold gain is decreased accordingly. When the change in air-gap length exceeds a certain value, the magnitude relationship of the threshold gains is reversed, and as the result, a mode hop occurs.

That is, the situation that a longitudinal mode with a wavelength near the center wavelength is switched as the result of a change in air-gap length is a factor of a mode hop.

It is to be noted that the above description does not consider a multimode state in which a plurality of longitudinal modes cause laser oscillation to occur simultaneously. In many cases, multimode oscillation is not desirable and a measure is taken to perform single mode operation. For example, single-mode oscillation can be performed by adjusting the current value or the like using the differences in threshold gain among the respective modes so that only a mode that most likely causes oscillation performs oscillation and the other modes do not cause oscillation.

In this specification, a phenomenon in which a mode that has relatively the lowest threshold gain and hence likely causes laser oscillation is switched to another longitudinal mode in a single-mode operation state in which only one longitudinal mode causes oscillation is called a mode hop.

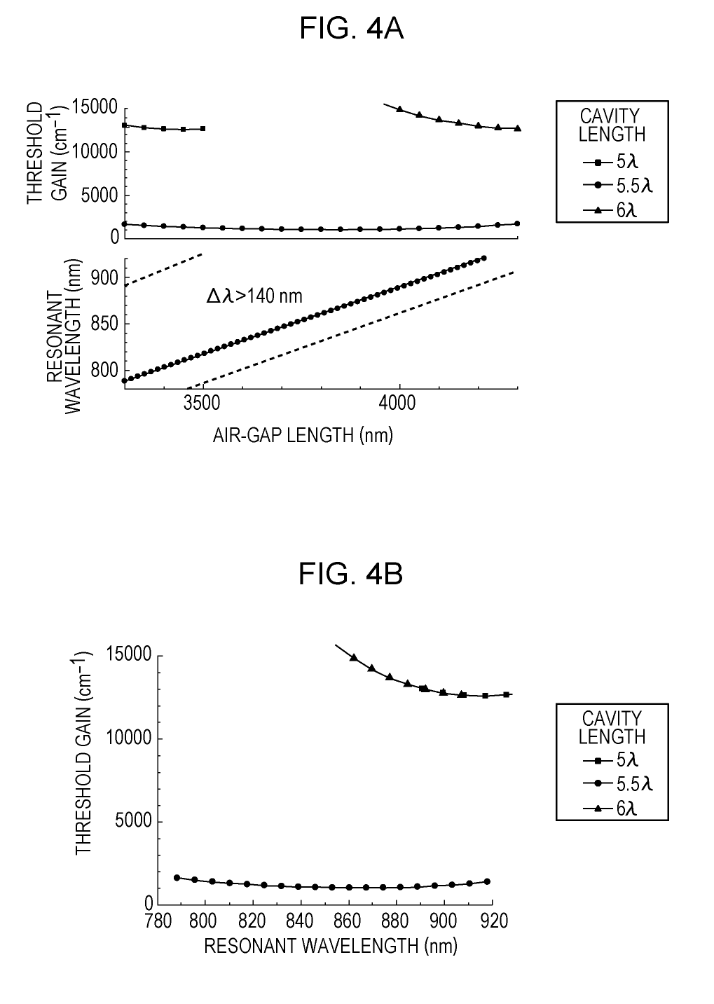

As described above, the wavelength variable width in a single mode of MEMS-VCSEL of related art is limited by a mode hop of a longitudinal mode. FIGS. 4A and 4B show the result of calculation for the relationship of the resonant wavelength and the gain (threshold gain) required for laser oscillation with respect to the change in air-gap length in the structure shown in FIG. 1.

Referring to an upper graph in FIG. 4A, it is found that the threshold gain is relatively small only in a specific longitudinal mode unlike FIG. 10A.

In the calculated range of wavelength and air-gap length, it is recognized that the threshold gain of a longitudinal mode corresponding to a cavity length of 5.5λ is constantly small, the magnitude relationship between the threshold gains is not reversed in a wide wavelength range of wavelengths larger than 140 nm, and hence a mode hop is restricted.

As compared with the calculation result of VCSEL of related art shown in FIG. 10A, it is found that the surface emitting laser according to this exemplary embodiment can provide the wavelength variable width that is twice or more of the wavelength variable width of the structure of related art.

FIG. 4B plots again the calculation result in FIG. 4A while the horizontal axis represents the resonant wavelength and the vertical axis represents the threshold gain.

The plotted lines for the longitudinal modes with the cavity lengths being 5λ and 6λ are substantially overlapped; however, only the threshold gain of the longitudinal mode being 5.5λ is relatively small.

As described above, in the surface emitting laser according to this exemplary embodiment, it is found that the threshold gain of only a specific longitudinal mode is small in a wide wavelength range, and wavelength sweeping in a wide band can be performed without occurrence of a mode hop. It is to be noted that the surface emitting laser according to this exemplary embodiment attains not only the effect of restricting a mode hop, but also an effect that the threshold gain becomes smaller than that of the related art structure in a specific longitudinal mode and hence laser oscillation can be easily performed according to comparison between FIGS. 4B and 10B.

### Light-Intensity Adjustment Unit

According to this exemplary embodiment, the light-intensity adjustment unit is only required to have a member with optical absorption (optical absorption member) or a member with optical gain (optical gain medium).

In this exemplary embodiment, the optical absorption member is a member with an absorption coefficient being a positive value.

For example, an optical absorption member with an absorption coefficient being 20 cm⁻¹ or larger, 50 cm⁻¹ or larger, 100 cm⁻¹ or larger, or 1000 cm⁻¹ or larger may be used.

In contrast, the optical gain medium is a member with an absorption coefficient being a negative value. For example, an optical gain medium with an absorption coefficient being −20 cm⁻¹ or smaller, −50 cm⁻¹ or smaller, −100 cm⁻¹ or smaller, or −1000 cm⁻¹ or smaller may be used.

The light-intensity adjustment unit may be entirely configured of the optical absorption member or the optical gain medium, or may be configured such that a layer with optical absorption or optical gain is arranged in part of the light-intensity adjustment unit. In this case, the layer with optical absorption or optical gain may be a single layer or may have a multilayer structure.

Described next is the thickness of the light-intensity adjustment unit, the thickness which is suitable for attaining the effects of the invention.

Important conditions desirable for attaining the effects of the invention include a condition that the difference in threshold gain between a longitudinal mode intended for laser oscillation and a neighbor-order longitudinal mode neighbor of the former longitudinal mode is large, and a condition that the threshold gain of the longitudinal mode intended for laser oscillation does not become excessively large. Even at the position of a node of a light distribution, optical absorption cannot be zero when the light-intensity adjustment unit providing light-intensity adjustment and having a limited thickness is arranged. Light is absorbed in accordance with the absorption coefficient and thickness of the material configuring the light-intensity adjustment unit.

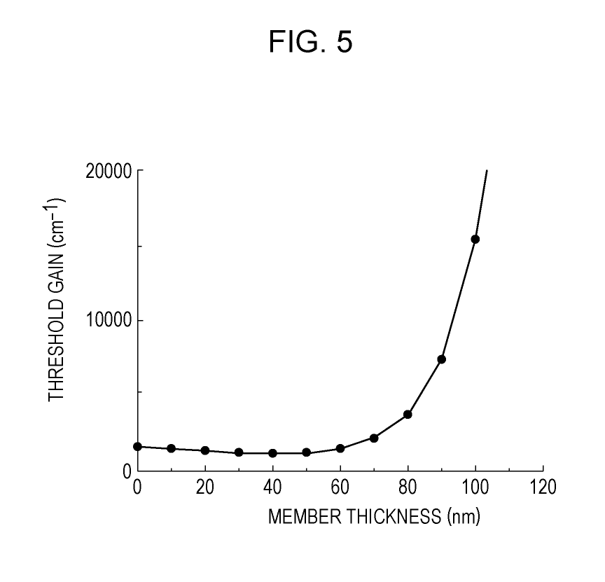

FIG. 5 shows an example result of calculation for the relationship between the thickness in the optical-axis direction and the threshold gain of the light-intensity adjustment unit 140 with the structure shown in FIG. 4B. The calculation was performed based on an assumption that the light-intensity adjustment unit 140 is configured of a member with uniform optical absorption and has an absorption coefficient of 1500 cm⁻¹.

An increase in threshold gain is not noticeable if the thickness of the light-intensity adjustment unit is about 60 nm. However, the threshold gain is rapidly increased if the thickness of the light-intensity adjustment unit is about 70 nm. This thickness corresponds to ¼ of the center wavelength of the surface emitting laser in terms of optical thickness.

Accordingly, the optical thickness in the optical-axis direction of the light-intensity adjustment unit is desirably ¼ of the center wavelength or smaller.

The material of the light-intensity adjustment unit is desirably properly selected with regard to the wavelength of light to be emitted by the surface emitting laser and the process of fabricating the light-intensity adjustment unit. The specific material of the light-intensity adjustment unit may be AlₓGa₍₁₋ₓ₎As (0<x<1), or more preferably, 0.6≦x≦0.8), GaAs, Si, or GaN. If a sacrificial layer process is used to fabricate the light-intensity adjustment unit by using such a material, the combination of the materials of the light-intensity adjustment unit, sacrificial layer, and etchant may be as follows. That is, the materials of “the light-intensity adjustment unit, sacrificial layer, and etchant” may be respectively desirably “AlₓGa₍₁₋ₓ₎As (0<x<1), GaAs, a citric acid solution and aqueous hydrogen peroxide,” “GaAs, AlGaInP or AlInP or GaInP, hydrochloric acid,” “GaAs, AlₓGa₍₁₋ₓ₎As (0.9≦x), BHF,” “Si, SiO₂, BHF,” or “GaN, (AlInN)Oₓ, NTA:KOH.”

### Upper Reflecting Mirror and Lower Reflecting Mirror

In the surface emitting laser according to this exemplary embodiment, the upper and lower reflecting mirrors are not particularly limited as long as the mirrors have reflectivities sufficient for laser oscillation. For example, DBR made of a dielectric or semiconductor multilayer film, a metal film, or a diffraction grating may be used.

An example of a dielectric multilayer film may be a film having a plurality of pairs of a silicon oxide layer (SiO₂ layer) serving as a low-refractive-index layer and a titanium oxide layer (TiO₂ layer) serving as a high-refractive-index layer.

In contrast, if a semiconductor multilayer film is used, the material configuring the semiconductor layer desirably has a material expressed by AlₓGa₍₁₋ₓ₎As (0≦x≦1). For example, a semiconductor multilayer film having a plurality of pairs of a GaAs layer serving as a high-refractive-index layer and an AlₓGa₍₁₋ₓ₎As layer (0.9≦x≦1) serving as a low-refractive-index layer. Also, AlAs satisfying x=1 may be used as the low-refractive-index layer.

The reflection bandwidth for high reflectivity and reflectivity can be controlled by properly changing the number of pairs of multilayer-film mirrors.

The structures and materials of the upper reflecting mirror and lower reflecting mirror according to this exemplary embodiment can be independently selected.

Also, one of the upper reflecting mirror and the lower reflecting mirror may be a diffraction grating, for example, a high contrast grating (hereinafter occasionally abbreviated as HCG) mirror. The HCG mirror has a configuration in which a material with a high refractive index and a material with a low refractive index are alternately periodically arranged in the in-plane direction. An example of the HCG mirror may be a periodic structure including a high-refractive-index region (AlGaAs portion) and a low-refractive-index region (air gap) provided with a periodic gap by processing a semiconductor layer such as an AlGaAs layer.

In the case of wavelength variable VCSEL, it is desirable to use a light-weight reflecting mirror for the reflecting mirror to be moved (in FIG. 1, the upper reflecting mirror) because the wavelength variable speed is increased. Owing to this, in this exemplary embodiment, the upper reflecting mirror desirably uses a HCG mirror with a thin (light-weight) configuration, instead of a multilayer-film mirror with a thick (heavy) configuration.

In the surface emitting laser according to this exemplary embodiment, the upper reflecting mirror is used as the reflecting mirror at the light extraction side; however, the lower reflecting mirror may be used as the reflecting mirror at the light extraction side. The reflecting mirror at the light extraction side has a peak reflectivity that is lower than the reflectivity of the other reflecting mirror.

The reflecting mirror for extracting light preferably has a value of reflectivity in a range from 99.0% to 99.5%.

Also, in general, comparing DBR configured of a dielectric with DBR configured of a semiconductor, the difference in refractive index of the dielectric DBR is more easily increased, and hence high reflectivity can be realized with a smaller number of stacked layers. In contrast, DBR configured of a semiconductor has advantages for processes that the lower reflecting mirror, active layer, and upper reflecting mirror can be collectively formed by crystal growth, and conductivity can be provided by doping. In the case of forming DBR with a semiconductor that cannot have a large difference in refractive index as compared with a dielectric, high reflectivity and a wide reflection band can be obtained by increasing the number of stacked layers.

In the above-described example, the surface emitting laser according to this exemplary embodiment drives the upper reflecting mirror and the light-intensity adjustment unit. However, an exemplary embodiment may be employed in which at least one of the upper reflecting mirror and the lower reflecting mirror, and the light-intensity adjustment unit are driven.

In the surface emitting laser according to this exemplary embodiment, since the light distribution in the cavity is changed in accordance with the laser oscillation wavelength, the position of the light-intensity adjustment unit may be required to be changed in accordance with the laser oscillation wavelength. Since the laser oscillation wavelength is changed in accordance with the positions of the upper reflecting mirror and the lower reflecting mirror, the position of the light-intensity adjustment unit may be required to be changed in accordance with the positions of the upper reflecting mirror and the lower reflecting mirror. That is, it may be desirable that the light-intensity adjustment unit and at least one of the upper reflecting mirror and the lower reflecting mirror are driven in an associated manner.

If the upper reflecting mirror and the lower reflecting mirror are periodically vibrated and wavelength sweeping is repetitively performed, the light-intensity adjustment unit is also desirably vibrated in the same period as the period of the upper reflecting mirror and the lower reflecting mirror.

At this time, the frequency of the vibration may be the mechanical resonant frequency of the upper reflecting mirror, the lower reflecting mirror, and the light-intensity adjustment unit, or may be other frequency.

In the surface emitting laser according to this exemplary embodiment, the displacement of the upper reflecting mirror and the displacement of the lower reflecting mirror have to be larger than the displacement of the light-intensity adjustment unit. Owing to this, if the vibration is made with a frequency closer to the resonant frequency of the upper reflecting mirror and the lower reflecting mirror than the resonant frequency of the light-intensity adjustment unit causes the amplitude of the upper reflecting mirror and the lower reflecting mirror to be easily increased. This may be occasionally convenient.

### Active Layer

The material of the active layer according to this exemplary embodiment is not particularly limited as log as the material generates light by injecting electric current, and may use a material used for a typical surface emitting laser. The composition and layer thickness of the material configuring the active layer may be properly selected in accordance with the wavelength intended for laser oscillation.

If light with a wavelength band around 850 nm is to be emitted, the active layer may use a material having a quantum well structure made of AlₙGa₍₁₋ₙ₎As (0≦n≦1). Also, if light with a wavelength band around 1060 nm is to be emitted, the active layer may use a material made of InₙGa₍₁₋ₙ₎As (0≦n≦1).

Also, the active layer according to this exemplary embodiment desirably has a sufficiently wide gain. To be specific, the active layer desirably has a gain in a wider wavelength region than the reflection band of the upper reflecting mirror and the lower reflecting mirror. Such an active layer may be an active layer having a quantum well structure capable of emitting light at two or more different energy levels. Also, the quantum well structure may be configured of a plurality of layers to have a single quantum well or multiple quantum wells.

The material and structure of the active layer according to this exemplary embodiment may be properly selected in accordance with the wavelength intended for oscillation.

Also, the active layer according to this exemplary embodiment may emit light by irradiation with light and excitation, or by current injection. Hence, the surface emitting laser according to this exemplary embodiment or an optical coherence tomography (described later) may have an exciting light source for exciting the active layer or a power supply for injecting electric current to the active layer. An electrode is required if light is emitted by current injection; however, the electrode is omitted in this specification and drawings for convenience of description.

### First Cladding Layer and Second Cladding Layer

In this exemplary embodiment of the present invention, a cladding layer is provided for trapping light and a carrier. Also, in this exemplary embodiment of the present invention, the cladding layer also has a role as a spacer for adjusting the cavity length.

The first cladding layer and the second cladding layer according to this exemplary embodiment may each use an AlGaAs layer in which the composition of Al is properly selected in accordance with the wavelength band for emission. For example, if light with a wavelength band around 850 nm is to be emitted, an AlGaAs layer with an Al composition being 30% or higher may be used to avoid optical absorption. Also, if light with a wavelength band around 1060 nm is to be emitted, a GaAs layer or an AlGaAs layer with a certain composition may be used because optical absorption does not have to be considered. When the active layer emits light by current injection, the conductivity type of the first cladding layer is different from that of the second cladding layer. The thickness of the first cladding layer does not have to be the same as that of the second cladding layer when the cladding layer thicknesses are adjusted, and the layer thicknesses may be properly selected with regard to the thicknesses required for current dispersion.

### Current Confinement Layer

In this exemplary embodiment, a current confinement layer (not shown) for limiting a region where current injected to the laser flows may be provided if required. The current confinement layer is formed by hydrogen ion implantation or by selectively oxidizing an AlGaAs layer with an Al composition of 90% or higher arranged in the cladding layer. In this exemplary embodiment, the current confinement layer is not particularly required for a structure that emits light by irradiation of the active layer with light and excitation. The current confinement layer is suitably used for a structure that emits light by current injection.

### Air Gap

A solid object is not generally present in the air gap according to this exemplary embodiment. Hence, the air gap may be in a vacuum, or fluid such as the air, inert gas, or liquid like water may be present in the air gap with regard to the atmosphere. The vacuum state in this case represents a negative-pressure state with an atmospheric pressure being lower than the standard atmospheric pressure. In this specification, it is expected that the air gap is filled with the air, and the calculation is performed with a refractive index of 1.

The length of the air gap (d in FIG. 1) may be determined with regard to the wavelength variable bandwidth and pull-in of the movable mirror. For example, in the cavity in which the air gap is filled with the air, the wavelength variable width is 100 nm with a wavelength around the center wavelength of 1060 nm, and the cavity length is in a range from 3λ to 4λ, the length d of the air gap is about 1 μm.

### Drive Unit

With the configuration to which the invention is applied, a unit configured to displace the upper reflecting mirror and the light-intensity adjustment unit in the vertical direction may use a technology typically used in the field of MEMS. For example, static electricity, piezoelectricity, heat, electromagnetism, a fluid pressure, or the like, may be used.

For example, there may be a drive unit that provides driving by applying a voltage with use of a MEMS mechanism, or a drive unit that provides driving by using a piezoelectric material. The drive unit may have a cantilever beam structure or a double-support beam structure.

In this exemplary embodiment, to properly control the positional relationship between the upper reflecting mirror and the light-intensity adjustment unit, a control unit configured to control the positions of the upper reflecting mirror and the light-intensity adjustment unit may be provided.

Also, a plurality of the surface emitting lasers according to this exemplary embodiment may be arranged on the same plane, and may be used as a light source array.

### Optical Coherence Tomography

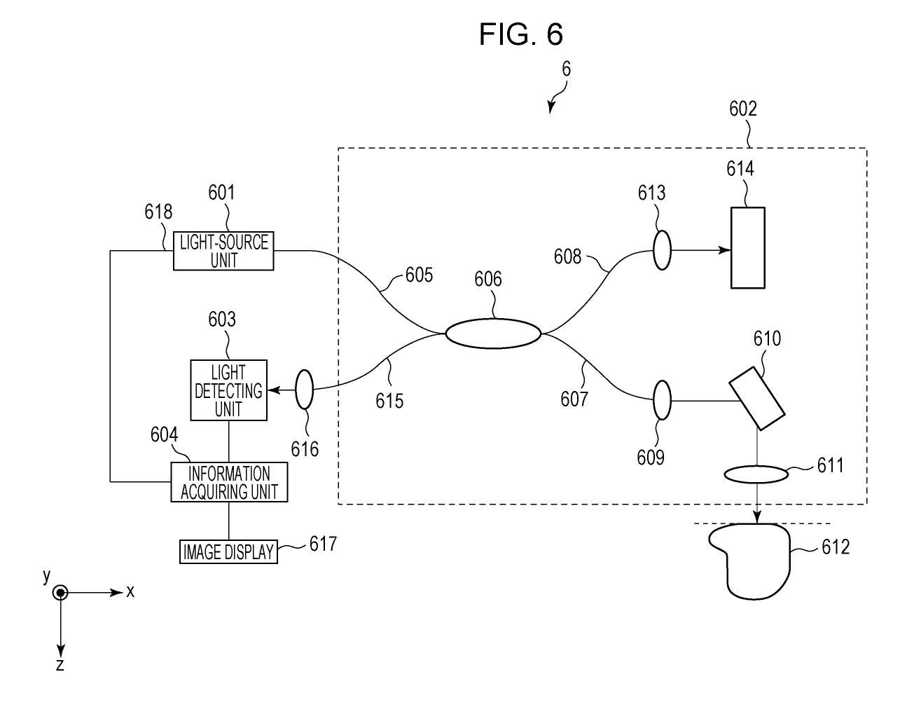

Since an optical coherence tomography (hereinafter, occasionally abbreviated as OCT) using the wavelength variable light source does not use a spectrometer, it is expected to acquire a tomographic image with a small loss in light quantity and a high S/N ratio. An example in which the surface emitting laser according to the exemplary embodiment is used for a light-source unit of OCT is described below with reference to FIG. 6.

An OCT device 6 according to this exemplary embodiment has a configuration including at least a light-source unit 601, an interference optical system 602, a light detecting unit 603, and an information acquiring unit 604; and can use the above-described surface emitting laser as the light-source unit 601. Although not shown, the information acquiring unit 604 has a Fourier transformer. The configuration that the information acquiring unit 604 has the Fourier transformer is not particularly limited as long as the information acquiring unit has a function of performing Fourier transform on input data. For example, the information acquiring unit 604 has an arithmetic unit and the arithmetic unit has a function of performing Fourier transform. To be specific, the arithmetic unit is a computer including CPU, and the computer executes an application having a Fourier transform function. For another example, the information acquiring unit 604 has a Fourier transform circuit having a Fourier transform function. Light output from the light-source unit 601 passes through the interference optical system 602, and is output as interfering light having information about an object 612 of a measurement object. The interfering light is received by the light detecting unit 603. The light detecting unit 603 may be a difference detecting type or a simple intensity monitoring type. Information of a temporal waveform with the intensity of the received interfering light is sent from the light detecting unit 603 to the information acquiring unit 604. The information acquiring unit 604 acquires the temporal waveform with the intensity of the received interfering light, performs Fourier transform, and hence acquires information (for example, information of a tomographic image) of the object 612. The light-source unit 601, the interference optical system 602, the light detecting unit 603, and the information acquiring unit 604 described above may be provided if desired.

A process from when light is oscillated from the light-source unit 601 to when the information of the tomographic image of the object as the measurement object is obtained is described in detail below.

The light output from the light-source unit 601 that changes the wavelength of light passes through a fiber 605, enters a coupler 606, and is split into irradiation light passing through an irradiation-light fiber 607 and reference light passing through a reference-light fiber 608. The coupler 606 is configured to operate in a single mode in the wavelength band of the light source. Various fiber couplers may be configured of 3 dB couplers. The irradiation light passes through a collimator 609, hence becomes parallel light, and is reflected by a mirror 610. The light reflected by the mirror 610 passes through a lens 611, is emitted on the object 612, and is reflected by respective layers in the depth direction of the object 612. In contrast, the reference light passes through a collimator 613, and is reflected by a mirror 614. In the coupler 606, interfering light is generated by the reflected light from the object 612 and the reflected light from the mirror 614. The interfering light passes through a fiber 615, passes through a collimator 616 to be collected, and is received by the light detecting unit 603. Information of the intensity of the interfering light received by the light detecting unit 603 is converted into electric information such as a voltage and is sent to the information acquiring unit 604. The information acquiring unit 604 processes the data of the intensity of the interfering light, or more particularly performs Fourier transform, and accordingly information of a tomographic image is obtained. The data of the intensity of the interfering light for Fourier transform is data generally sampled every equivalent number of waves by using k clock. However, data sampled at every equivalent wavelength may be also used.

The obtained information of the tomographic image may be sent from the information acquiring unit 604 to an image display 617 and displayed as an image. By scanning the mirror 610 in a plane perpendicular to the incidence direction of the irradiation light, a three-dimensional tomographic image of the object 612 of the measurement object can be obtained. Also, the light-source unit 601 may be controlled by the information acquiring unit 604 by using an electric circuit 618. Although not shown, the intensity of light output from the light-source unit 601 may be successively monitored and the data may be used for correcting the amplitude of a signal indicating the intensity of the interfering light. The surface emitting laser according to the exemplary embodiment of the invention can oscillate a laser beam in a wide band while restricting an increase in threshold current for emitting a laser beam and a decrease in light emission efficiency. Hence, if the surface emitting laser according to this exemplary embodiment is used for the OCT device, a tomographic image with a high depth resolution can be obtained while electric current for outputting a laser beam is decreased.

The OCT device according to the exemplary embodiment is suitable for acquiring a tomographic image of a living body, such as an animal or a human, in the fields of ophthalmology, dentistry, dermatology, etc. The information relating to a tomographic image of a living body includes not only a tomographic image of a living body but also numerical data required for acquiring a tomographic image.

In particular, when a measurement object is an eye fundus of a human body, it is desirable to use numerical data to acquire information relating to a tomographic image of the eye fundus.

### Other Purposes

The surface emitting laser according to the exemplary embodiment of the invention can be used as a light source for optical communication or a light source for optical measurement, in addition to the above-described OCT.

### EXAMPLES

Examples of the invention are described below. It is to be noted that the invention is not limited to the configurations of the examples described below. For example, the kind, composition, shape, and size of a material may be properly changed within the scope of the invention.

In the following examples, the laser oscillation wavelength around 1060 nm and the laser oscillation wavelength around 850 nm are provided. However, an operation can be made with a desirable wavelength by selecting a proper material and a proper structure.

### Example 1

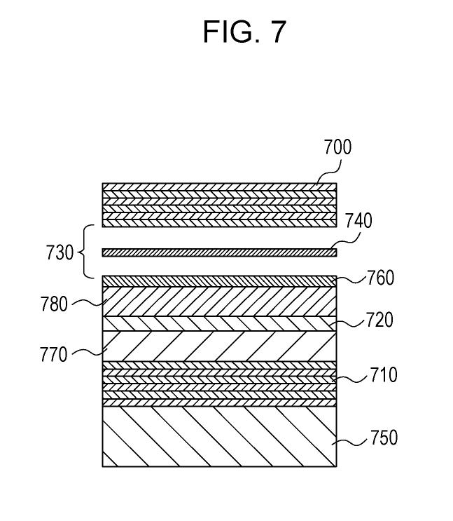

As EXAMPLE 1, VCSEL according to this example is described with reference to FIG. 7. FIG. 7 is a schematic cross-sectional view showing a layer structure of VCSEL according to this example.

The VCSEL according to this example is configured of a compound semiconductor based on GaAs, and is designed to perform wavelength sweeping around the center wavelength of 1060 nm.

An upper reflecting mirror 700, an air gap 730, an antireflection film 760, an upper cladding layer 780, an active layer 720, a lower cladding layer 770, a lower reflecting mirror 710, and a GaAs substrate 750 are arranged in that order from the upper side. A light-intensity adjustment unit 740 is arranged in the air gap 730. The light-intensity adjustment unit 740 is configured of an Al_{0.7}Ga_{0.3}As layer with a thickness of 75 nm, and has an absorption coefficient of about 500 cm⁻¹ by doping with an impurity.

The antireflection film 760 is formed of an oxidized AlAs layer with an optical thickness being ¼ of the center wavelength of the surface emitting laser according to this example.

The cavity length is configured to correspond to about 7.5λ when the center wavelength of 1060 nm is 1λ.

The upper reflecting mirror is DBR configured by alternately staking 36.5 pairs of Al_{0.4}Ga_{0.6}As and Al_{0.9}Ga_{0.1}As.

The lower reflecting mirror is DBR configured by alternately stacking 30 pairs of GaAs and AlAs and then alternately stacking 5 pairs of Al_{0.4}Ga_{0.6}As and Al_{0.9}Ga_{0.1}As.

The active layer is configured of a quantum well structure formed by alternately stacking a 8-nm-thick In_{0.27}Ga_{0.73}As layer and a 10-nm-thick GaAsP layer for 3 periods.

The active layer is configured to emit light by current injection. In the drawing, an electrode for current injection is omitted.

The positions of the upper reflecting mirror 700 and the light-intensity adjustment unit 740 can be changed in the vertical direction by an electrostatic force by application of a voltage. Also in this case, an electrode for voltage application is omitted in the drawing.

The light-intensity adjustment unit 740 is arranged at a position separated by about 3λ from the upper reflecting mirror 700. The position of the light-intensity adjustment unit 740 is controlled so that the light-intensity adjustment unit 740 is displaced only by 60% of the displacement of the upper reflecting mirror 700.

The air gap of this example is formed by using epitaxial growth and selective wet etching. The process is briefly described.

When epitaxial growth is performed, a portion corresponding to the air gap is formed as a sacrificial layer of GaAs.

By using a mixed solution of water, citric acid, and aqueous hydrogen peroxide, as etchant, selective etching corresponding to the Al composition of AlGaAs can be performed. In this example, a solution in which a citric acid solution obtained by mixing water and citric acid (weight ratio of 1:1) and aqueous hydrogen peroxide with a density of 30% are mixed at the ratio of 4:1, and the solution is used as etchant. With this etchant, selective etching of GaAs and Al_{0.7}Ga_{0.3}As can be performed. By eliminating only the GaAs sacrificial layer, the air gap can be formed.

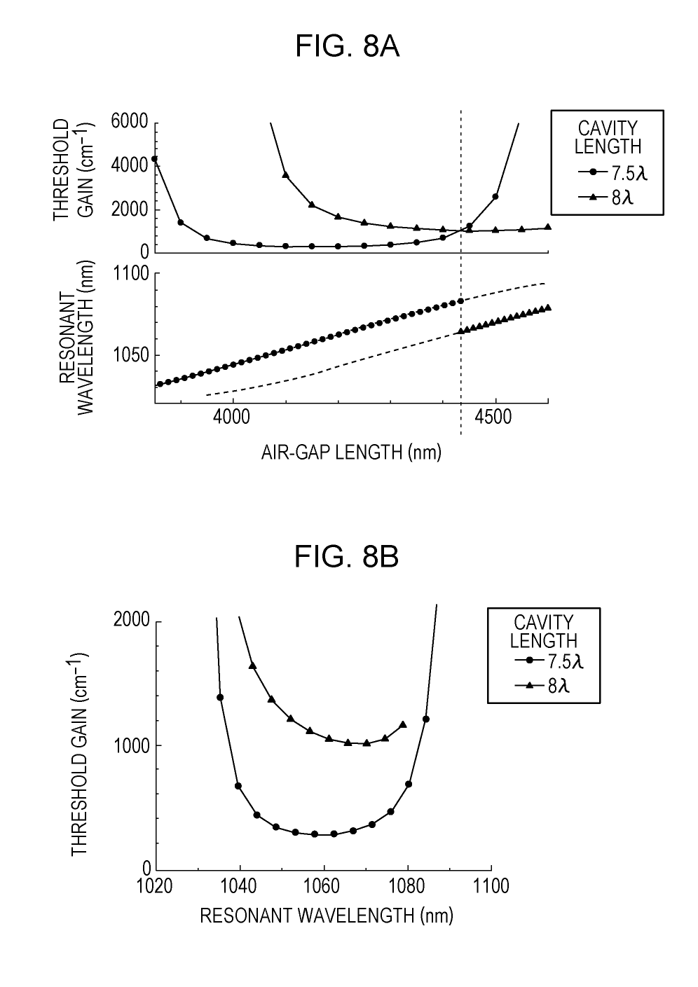

FIG. 8A shows the result of calculation for the relationship of the resonant wavelength and the gain (threshold gain) required for laser oscillation with respect to the air-gap length of the structure shown in FIG. 7.

Referring to an upper graph in FIG. 8A, it is found that a longitudinal mode corresponding to a cavity length of 7.5λ has a smaller threshold gain than a longitudinal mode corresponding to a cavity length of 8λ.

In a major part of the range of the calculated wavelength and the air-gap length, it can be recognized that the threshold gain of a longitudinal mode corresponding to a cavity length of 7.5λ is relatively small and a mode hop is restricted.

FIG. 8B shows a graph expressing the calculation result in FIG. 8A in a different form. FIG. 8B plots again the calculation result in FIG. 8A while the horizontal axis represents the resonant wavelength and the vertical axis represents the threshold gain.

While the plotted lines for the longitudinal modes with the cavity lengths being 7.5λ and 8λ are plotted, the line of the longitudinal mode with 7.5λ has a relatively small threshold gain.

As described above, in the configuration to which the invention is applied, the threshold gain of only a specific longitudinal mode is small in a wide wavelength range, and wavelength sweeping in a wide band can be performed without occurrence of a mode hop.

### Example 2

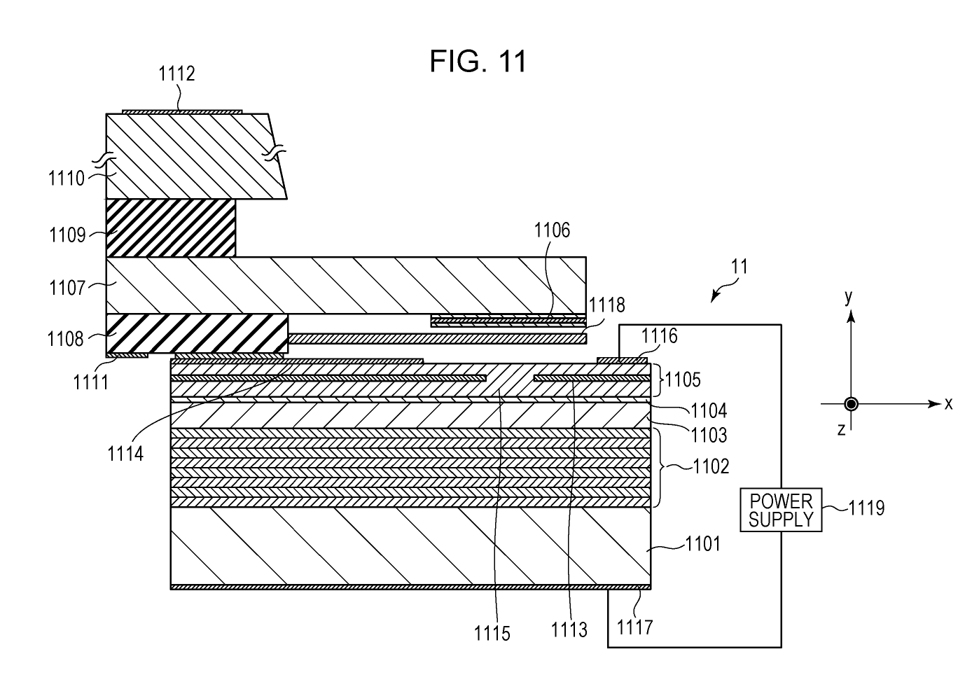

FIG. 11 shows a schematic illustration explaining a configuration of a surface emitting laser according to EXAMPLE 2. In FIG. 11, an n-type multilayer-film mirror 1102 is provided on an n-type semiconductor substrate 1101 formed of a GaAs layer as a III-V group compound semiconductor. The n-type multilayer-film mirror (DBR) 1102 is a stack body in which 45 pairs of an Al_{0.8}GaAs layer (68.1-nm-thick) and an Al_{0.3}GaAs layer (62-nm-thick) as III-V group compound semiconductors are repetitively stacked.

On the multilayer-film mirror (DBR) 1102, an n-type cladding layer 1103 formed of an Al_{0.8}GaAs layer (102.6-nm-thick) is provided. On the n-type cladding layer 1103, an active layer 1104 having a triple quantum well structure formed of a combination of a GaAs well layer (10-nm-thick) and an Al_{0.3}GaAs barrier layer (10-nm-thick) is provided. Also, on the active layer 1104, a p-type cladding layer 1105 formed of an Al_{0.8}GaAs layer (337.4-nm-thick) is further provided.

A movable mirror 1106 is provided on a lower surface of a portion at a distal end side of a silicon cantilever (2-μm-thick) 1107. The silicon cantilever 1107 is supported above the substrate 1101 with multiple layers interposed therebetween, by a silicon oxide layer (1-μm-thick) 1108, the silicon cantilever (2-μm-thick) 1107, a silicon oxide film (2.5-μm-thick) 1109, and a silicon substrate 1110. The movable mirror 1106 is a dielectric DBR in which 10 pairs of a SiO₂ layer (145.5-nm-thick) and a TiO₂ layer (90-nm-thick) are repetitively stacked. The layer thickness of the silicon oxide layer 1108 corresponds to the thickness of the air gap, and the cavity length in a state in which the movable mirror is not driven is 3λ. Also, a Ti/Au electrode 1111 and a Ti/Au electrode 1112 are formed for application of a voltage to drive the silicon cantilever by an electrostatic attraction.

In this example, the movable mirror 1106 is provided on the lower surface of the portion at the distal end side of the silicon cantilever 1107; however, the movable mirror 1106 may be provided on an upper surface and part of the portion at the distal end side of the silicon cantilever 1107 may be removed.

Also, the cladding layer 1105 has a current confinement layer 1113 formed by ion implantation with protons in part of the p-type cladding layer 1105. Hence, current supplied from an electrode 1116 passes through an opening portion 1115 of the current confinement layer 1113, and is injected to the active layer 1104. As an electrode for driving the wavelength variable VCSEL of this example, an electrode 1116 uses a metal multilayer film formed of a Ti layer (20 nm) and an Au layer (100 nm). Also, an electrode 1117 uses a metal multilayer film formed of mixed crystal of Au and Ge (100 nm), Ni (20 nm), and Au (100 nm).

Also, the electrodes 1114 and 1112 each use a metal multilayer film formed of a Ti layer (20 nm) and an Au layer (100 nm). Reference sign 1119 denotes a power supply for driving VCSEL.

In this example, a silicon MEMS structure formed by processing a silicon on insulator (SOI) substrate is used as a drive unit having the emission-side movable mirror (upper mirror) 1106. In the drive unit, the compound semiconductor substrate 1101 having formed thereon the lower multilayer-film mirror (DBR) 1102, the lower cladding layer 1103, the active layer 1104, the upper cladding layer 1105, etc., is bonded, and hence a wavelength variable VCSEL 11 is configured.

In this example, it is assumed that a light emission region determined by a proton injection region, that is, the opening portion 1115 of the current confinement structure formed by ion implantation with protons has a circular shape with a diameter of 5 μm.

In this example, a light-intensity adjustment unit 1118 is provided. By displacing the light-intensity adjustment unit 1118, the movable mirror (upper reflecting mirror) 1106, and the multilayer-film mirror (lower reflecting mirror) 1102 as described above, a mode hop can be restricted, and the wavelength variable width can be enlarged.

Next, a manufacturing method of the wavelength variable VCSEL according to this example is described.

First, the multilayer-film mirror (n-type semiconductor DBR) 1102, the n-type cladding layer 1103, the active layer 1104, and the p-type cladding layer 1105 are successively stacked on the n-type semiconductor substrate 1101 formed of a GaAs layer by using a metal organic chemical vapor deposition (MOCVD) crystal growth technology.

Then, a silicon oxide film is formed on the p-type cladding layer 1105, and is processed by a photolithography technology and an etching technology to serve as a mask when protons are injected for forming the current confinement structure. After the mask of the silicon oxide film (not shown) is formed, protons are injected, and hence the current confinement structure is formed. Alternatively, to form the current confinement structure, an AlGaAs layer (30-nm-thick) with an Al composition of 90% or higher may be arranged in the cladding layer 1105, and the portion may be selectively oxidized in the x-axis direction from the side surface to be converted into aluminum oxide hence to be a region with high resistance.

Then, the electrode 1116 is formed by using a photolithography technology, a vacuum deposition technology, and a lift-off technology.

Then, the cathode electrode 1117 for driving VCSEL is formed on the back surface of the semiconductor substrate 1101 by using a vacuum deposition technology, and thus a compound semiconductor light emitting element is completed.

Alternatively, the conductive types of the respective semiconductor layers in the above-described example may be inverted. In particular, the p-type semiconductor layer may be the n-type semiconductor layer, and the n-type semiconductor layer may be the p-type semiconductor layer. The dopant of the p-type semiconductor layer may use Zn, and the dopant of the n-type semiconductor layer may use C; however, it is not limited thereto.

It is expected that the wavelength variable VCSEL of this example performs wavelength sweeping in the variable wavelength band of ±50 nm around the wavelength of 850 nm. However, the wavelength band is not limited to this wavelength band. By properly selecting the materials of the respective layers configuring the VCSEL, for example, wavelength sweeping may be performed in a wavelength band of ±50 nm around the wavelength of 1060 nm.

### Example 3

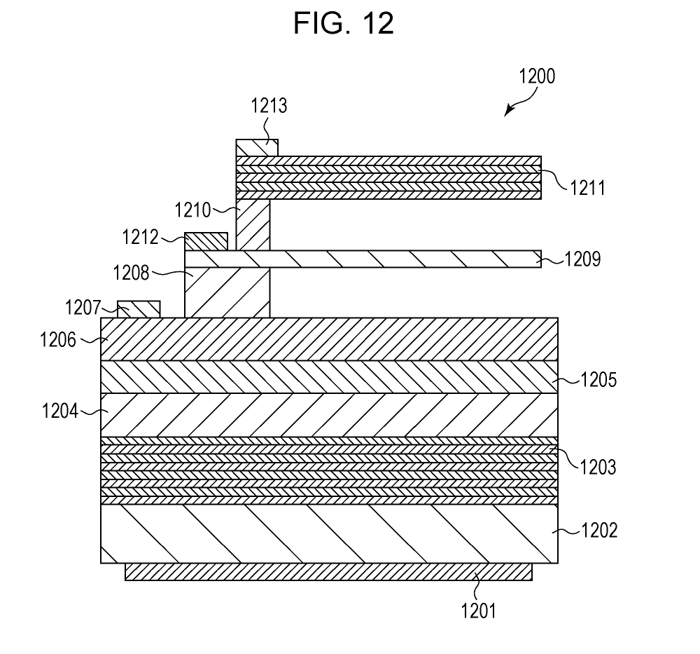

A surface emitting laser according to EXAMPLE 3 is described with reference to FIG. 12. FIG. 12 is a schematic cross-sectional view showing a layer structure of VCSEL according to this example.

VCSEL 1200 according to this example includes a cathode electrode 1201 for driving VCSEL, an n-type substrate 1202 configured of GaAs, an n-type lower DBR 1203 formed by alternately stacking AlAs and GaAs by 40.5 pairs, an n-type lower spacer layer 1204 configured of Al_{0.7}Ga_{0.3}As, an undoped active layer 1205 configured of a multilayer quantum well layer formed of a quantum well layer of InGaAs and a barrier layer of GaAsP, and a p-type upper spacer layer 1206 configured of Al_{0.7}Ga_{0.3}As in that order. Also, an electrode 1207 for driving VCSEL and for driving upper DBR is formed on the upper spacer layer 1206. Further, an undoped GaAs layer 1208, an n-type slab portion 1209 configured of Al_{0.7}Ga_{0.3}As, an undoped GaAs layer 1210, an n-type upper DBR 1211 formed by arranging Al_{0.7}Ga_{0.3}As at the upper and lower outermost layers and alternately stacking Al_{0.9}Ga_{0.1}As and Al_{0.4}Ga_{0.6}As by 30 pairs between the upper and lower outermost layers, and electrodes 1212 and 1213 for driving upper DBR 1112 are formed on the upper spacer layer 1206.

The structure of this example is fabricated by using a typical semiconductor process technology such as epitaxial growth, photolithography, dry etching, wet etching, vacuum deposition, etc., similarly to the technologies described in EXAMPLES 1 and 2.

A semiconductor multilayer film is formed on the substrate 1202 by epitaxial growth to the upper DBR 1211.

Next, photolithography and dry etching are performed by two times, and a beam structure including the slab portion 1209 and the upper DBR 1211 are patterned. At this time, it is assumed that the depth of the dry etching is a depth that causes the GaAs sacrificial layer 1208 to be exposed.

Next, portions of the GaAs sacrificial layer 1208 and the GaAs sacrificial layer 1210 are removed by wet etching using a mixed solution of a citric acid solution and aqueous hydrogen peroxide, and hence the beam structure is formed. At this time, if portions of the sacrificial layers are covered with photoresist or the like, the region of the portions of the sacrificial layers can be left without being removed.

Next, the electrode 1207, the electrode 1212, and the electrode 1213 are formed by using photolithography, vacuum deposition, and lift-off.

Next, the cathode electrode 1201 for driving VCSEL is formed on the back surface of the semiconductor substrate 1202 by using a vacuum deposition technology, and thus a compound semiconductor light emitting element is completed.

With the surface emitting laser according to the exemplary embodiment and the examples of the invention, by properly displacing at least two of the light-intensity adjustment unit provided in the air gap of the surface emitting laser, and the upper reflecting mirror and the lower reflecting mirror, oscillation becomes easily continued in a certain longitudinal mode. To be specific, optical absorption for light in a specific longitudinal mode is set to be relatively smaller than optical absorption for light in its neighbor longitudinal mode, or optical gain for light in a specific longitudinal mode is set to be relatively larger than optical gain for light in its neighbor longitudinal mode. Consequently, a mode hop in a longitudinal mode can be restricted, and the wavelength variable width can be enlarged.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-135389 filed Jun. 30, 2014, which is hereby incorporated by reference herein in its entirety.

What is claimed is:

1. A surface emitting laser including a lower reflecting mirror, an active layer, and an upper reflecting mirror in that order, having an air gap between the active layer and the upper reflecting mirror, and being able to change a wavelength of light to be emitted, the surface emitting laser comprising:
a light-intensity adjustment unit provided on an optical path of the air gap and having optical absorption or optical gain in a wavelength range of emission light of the surface emitting laser,
wherein the wavelength of the light to be emitted is changed by displacing the light-intensity adjustment unit and at least one of the upper reflecting mirror and the lower reflecting mirror.

2. The surface emitting laser according to claim 1, wherein the light-intensity adjustment unit has a member having optical absorption in the wavelength range of the emission light of the surface emitting laser, and wherein a center in an optical-axis direction of the light-intensity adjustment unit is located in a range that is ±⅛ times a center wavelength of the surface emitting laser in the optical-axis direction from a position of a certain node of a specific mode of a standing light wave that is formed in a cavity configured of the upper reflecting mirror and the lower reflecting mirror.

3. The surface emitting laser according to claim 2, wherein the light-intensity adjustment unit has an absorption coefficient of 20 cm⁻¹ or larger.

4. The surface emitting laser according to claim 2, wherein the light-intensity adjustment unit has an absorption coefficient of 100 cm⁻¹ or larger.

5. The surface emitting laser according to claim 1,
wherein the light-intensity adjustment unit has a member having optical gain in the wavelength range of the emission light of the surface emitting laser, and
wherein a center in an optical-axis direction of the light-intensity adjustment unit is located in a range that is ±⅛ times a center wavelength of the surface emitting laser in the optical-axis direction from a position of a certain antinode of a specific mode of a standing light wave that is formed in a cavity configured of the upper reflecting mirror and the lower reflecting mirror.

6. The surface emitting laser according to claim 5, wherein the light-intensity adjustment unit has an absorption coefficient of −20 cm⁻¹ or smaller.

7. The surface emitting laser according to claim 5, wherein the light-intensity adjustment unit has an absorption coefficient of −100 cm⁻¹ or smaller.

8. The surface emitting laser according to claim 1, wherein the light-intensity adjustment unit has an optical thickness in an optical-axis direction, the optical thickness being smaller than ¼ of a center wavelength of the surface emitting laser.

9. The surface emitting laser according to claim 1, wherein at least two of the light-intensity adjustment unit, the upper reflecting mirror, and the lower reflecting mirror are displaced synchronously.

10. The surface emitting laser according to claim 1, wherein at least two of the light-intensity adjustment unit, the upper reflecting mirror, and the lower reflecting mirror are displaced in the same period.

11. An optical coherence tomography comprising:
a light-source unit configured to change a wavelength of light;
an interference optical system configured to split the light from the light-source unit into irradiation light that is emitted on an object and reference light, and generate interfering light from reflected light of the light emitted on the object and the reference light;
a light detecting unit configured to receive the interfering light; and
an information acquiring unit configured to process a signal from the light detecting unit and acquires information of the object,
wherein the light-source unit is the surface emitting laser according to claim 1.
